(19) United States
(12) Patent Application Publication
(10) Pub. No.: US 2025/0176199 A1
(43) Pub. Date: May 29, 2025

(54) SCHOTTKY BARRIER DIODE

(71) Applicant: TDK Corporation, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 19/041,014

(22) Filed: Jan. 30, 2025

Related U.S. Application Data
(63) Continuation of application No. PCT/JP2023/018393, filed on May 17, 2023.

(30) Foreign Application Priority Data
Aug. 31, 2022 (JP) 2022-137729

(51) Int. Cl. H10D 8/60; H10D 62/10

(52) U.S. Cl. CPC H10D 8/60; H10D 62/124

(57) ABSTRACT

Disclosed herein is a Schottky barrier diode that includes a semiconductor substrate and a drift layer, an anode electrode contacting the drift layer, and a cathode electrode contacting the semiconductor substrate. The drift layer has an outer peripheral trench surrounding the anode electrode. The outer peripheral trench includes an inner peripheral wall, an outer peripheral wall, a bottom surface, an inner peripheral corner connecting the inner peripheral wall and the bottom surface, and an outer peripheral corner connecting the outer peripheral wall and the bottom surface. The inner peripheral wall and the inner peripheral corner of the outer peripheral trench are covered with the anode electrode through an insulating film. The outer peripheral corner of the outer peripheral trench is covered with a semiconductor material having a conductivity type opposite to a conductivity type of the drift layer.

### CROSS-REFERENCE TO RELATED APPLICATION

This application claims the benefit of Japanese Patent Application No. 2022-137729, filed on Aug. 31, 2022, the entire disclosure of which is incorporated by reference herein.

### BACKGROUND OF THE ART

### Field of the Art

The present disclosure relates to a Schottky barrier diode.

### Description of Related Art

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (SiC), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of 8 MV/cm, so that a Schottky barrier diode using gallium oxide is very promising as the switching element for a power device. An example of the Schottky barrier diode using gallium oxide is described in JP 2019-179815A.

In the Schottky barrier diode described in JP 2019-179815A, an outer peripheral trench is formed in a drift layer made of gallium oxide so as to surround an anode electrode in a plan view and is filled with a semiconductor material having a conductivity type opposite to that of the drift layer. With this structure, when a backward voltage is applied, a depletion layer extends around the outer peripheral trench due to a potential difference between the semiconductor material filled in the outer peripheral trench and the drift layer, with result that electric field concentration at corners of the anode electrode is relaxed to make dielectric breakdown unlikely to occur.

### SUMMARY

The present disclosure describes a technology to further relax, in a Schottky barrier diode, an electric field which is generated in the drift layer upon application of a backward voltage.

A Schottky barrier diode according to the present disclosure includes: a semiconductor substrate; a drift layer provided on the semiconductor substrate; an anode electrode brought into Schottky contact with the drift layer; and a cathode electrode brought into ohmic contact with the semiconductor substrate. The drift layer has an outer peripheral trench surrounding the anode electrode in a plan view. The outer peripheral trench includes an inner peripheral wall, an outer peripheral wall, a bottom surface, an inner peripheral corner connecting the inner peripheral wall and the bottom surface, and an outer peripheral corner connecting the outer peripheral wall and the bottom surface. The inner peripheral wall of the outer peripheral trench and the inner peripheral corner of the outer peripheral trench are covered with the anode electrode through an insulating film, and the outer peripheral corner of the outer peripheral trench is covered with a semiconductor material having a conductivity type opposite to a conductivity type of the drift layer.

### BRIEF DESCRIPTION OF THE DRAWINGS

The above features and advantages of the present disclosure will be more apparent from the following description of some embodiments taken in conjunction with the accompanying drawings, in which:

FIG. 1A is a schematic plan view illustrating the configuration of a Schottky barrier diode 1 according to a first embodiment of the present disclosure;

FIG. 1B is a schematic cross-sectional view taken along the line A-A in FIG. 1A;

FIG. 2 is a schematic diagram for explaining the definition of the inner peripheral corner 36 and the outer peripheral corner 37;

FIG. 3 is a graph illustrating the relation between field strength to be applied to the drift layer 30 upon application of a backward voltage of 1200 V and plane position;

FIG. 4 is a schematic cross-sectional view showing the configuration of a Schottky barrier diode according to a comparative example;

FIG. 5 is a schematic cross-sectional view illustrating the configuration of a Schottky barrier diode 2 according to a second embodiment of the present disclosure;

FIG. 6 is a schematic cross-sectional view illustrating the configuration of a Schottky barrier diode 3 according to a third embodiment of the present disclosure;

FIG. 7 is a schematic cross-sectional view illustrating the configuration of a Schottky barrier diode 4 according to a fourth embodiment of the present disclosure;

FIG. 8 is a schematic cross-sectional view illustrating the configuration of a Schottky barrier diode 5 according to a fifth embodiment of the present disclosure;

FIG. 9 is a schematic cross-sectional view illustrating the configuration of a Schottky barrier diode 6 according to a sixth embodiment of the present disclosure;

FIG. 10 is a schematic cross-sectional view illustrating the configuration of a Schottky barrier diode 7 according to a seventh embodiment of the present disclosure;

FIG. 11 is a schematic cross-sectional view illustrating the configuration of a Schottky barrier diode 8 according to an eighth embodiment of the present disclosure;

FIG. 12 is a schematic cross-sectional view illustrating the configuration of a Schottky barrier diode 9 according to a ninth embodiment of the present disclosure;

FIG. 13 is a schematic cross-sectional view illustrating the configuration of a Schottky barrier diode 10 according to a tenth embodiment of the present disclosure;

FIG. 14 is a schematic cross-sectional view illustrating the configuration of a Schottky barrier diode 11 according to an eleventh embodiment of the present disclosure;

FIG. 15 is a schematic cross-sectional view illustrating the configuration of a Schottky barrier diode 12 according to a twelfth embodiment of the present disclosure;

FIG. 16 is a schematic cross-sectional view illustrating the configuration of a Schottky barrier diode 13 according to a thirteenth embodiment of the present disclosure;

FIG. 17 is a schematic cross-sectional view illustrating the configuration of a Schottky barrier diode 14 according to a fourteenth embodiment of the present disclosure;

FIG. 18A is a schematic plan view illustrating the configuration of a Schottky barrier diode 15 according to a fifteenth embodiment of the present disclosure; and

FIG. 18B is a schematic cross-sectional view taken along the line A-A in FIG. 18A.

### DETAILED DESCRIPTION OF THE EMBODIMENTS

Hereinafter, some embodiments of the present disclosure will be described in detail with reference to the accompanying drawings.

### First Embodiment

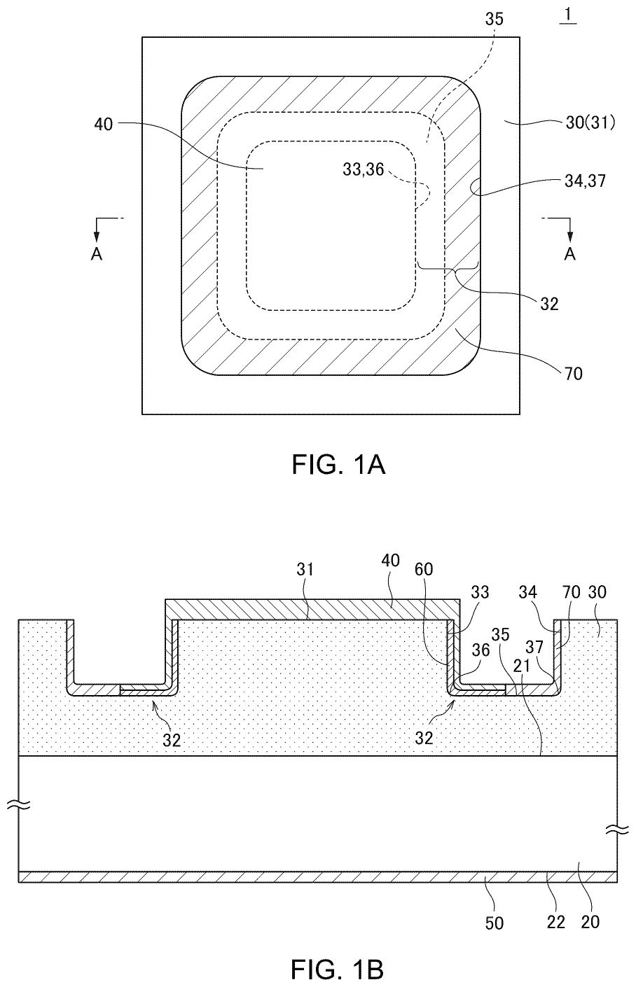

FIG. 1A is a schematic plan view illustrating the configuration of a Schottky barrier diode 1 according to a first embodiment of the present disclosure. FIG. 1B is a schematic cross-sectional view taken along the line A-A in FIG. 1A.

As illustrated in FIGS. 1A and 1B, the Schottky barrier diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n⁻ layer, respectively. The dopant concentration of the semiconductor substrate 20 may be about 1×10¹⁸ cm⁻³, and the dopant concentration of the drift layer 30 may be about 1×10¹⁶ cm⁻³.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20 A, the planar size may be set to be about 2.4 mm×2.4 mm.

The semiconductor substrate 20 has an upper surface 21 positioned on the upper surface side in its mounted state and a back surface 22 positioned opposite the upper surface 12 and on the lower surface side in its mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 1200 V, the film thickness may be set to be about 10 μm.

There is formed, on an upper surface 31 of the drift layer 30, an anode electrode 40 which is brought into Schottky contact with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50 which is brought into ohmic contact with the semiconductor substrate 20. The cathode electrode 50 is formed of metal such as titanium (Ti). The cathode electrode 50 may have a multilayer structure of different metal films, such as Ti/Au or Ti/Al.

In the present embodiment, a ring-shaped outer peripheral trench 32 is formed at the upper surface 31 side of the drift layer 30. The outer peripheral trench 32 can be formed by etching the drift layer 30 from its upper surface 31 side. The anode electrode 40 is disposed in an area surrounded by the outer peripheral trench 32. The width of the outer peripheral trench 32 is, for example, about 10 μm, and the depth thereof is, for example, about 2 μm.

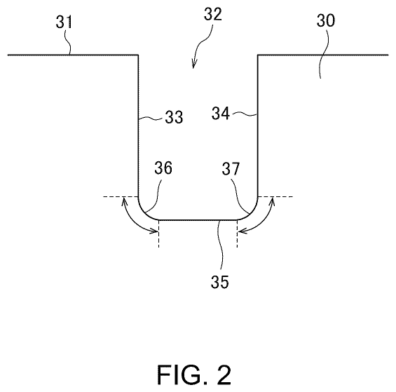

As illustrated in FIGS. 1A and 1B, the outer peripheral trench 32 includes an inner peripheral wall 33, an outer peripheral wall 34, a bottom surface 35, an inner peripheral corner 36 connecting the inner peripheral wall 33 and the bottom surface 35, and an outer peripheral corner 37 connecting the outer peripheral wall 34 and the bottom surface 35. The inner peripheral wall 33 and outer peripheral wall 34 are inner wall surfaces of the outer peripheral trench 32 that are substantially parallel to the layer stacking direction, in other words, substantially perpendicular to the upper surface 31 of the drift layer 30. The bottom surface 35 is an inner wall surface of the outer peripheral trench 32 that is substantially parallel to the upper surface 31 of the drift layer 30. The inner peripheral corner 36 is a portion connecting the inner peripheral wall 33 and the bottom surface 35, and the outer peripheral corner 37 is a portion connecting the outer peripheral wall 34 and the bottom surface 35. The inner peripheral corner 36 and outer peripheral corner 37 may each be sharply angled at 90 degrees or may each be curved. As illustrated in FIG. 2, when the inner peripheral corner 36 and outer peripheral corner 37 are curved, the curved surface positioned between the inner peripheral wall 33 and the bottom surface 35 corresponds to the inner peripheral corner 36, and the curved surface positioned between the outer peripheral wall 34 and the bottom surface 35 corresponds to the outer peripheral corner 37.

In the Schottky barrier diode 1 according to the present embodiment, the inner peripheral wall 33 of the outer peripheral trench 32, the inner peripheral corner 36 thereof, and a part of the bottom surface 35 thereof are covered with the anode electrode 40 through an insulating film 60. In the outer peripheral trench 32, the insulating film 60 is interposed between the anode electrode 40 and the drift layer 30, so that the anode electrode 40 does not directly contact the drift layer 30. As the material of the insulating film 60, an insulating material having a high dielectric constant, such as HfO₂ or Al₂O₃, is desirably used. The thickness of the insulating film 60 can be set to be, for example, about 50 nm. Thus, withstand voltage effect is enhanced.

On the other hand, the outer peripheral wall 34 of the outer peripheral trench 32, the outer peripheral corner 37 thereof, and the remaining part of the bottom surface 35 thereof are directly covered with a semiconductor material 70 having a conductivity type opposite to that of the drift layer 30. In the present embodiment, the drift layer 30 has an n-conductivity type, so that the semiconductor material 70 positioned in the outer peripheral trench 32 has a p-conductivity type. In the example illustrated in FIG. 1, the end face positions of the anode electrode 40 and semiconductor material 70 on the bottom surface 35 of the outer peripheral trench 32 coincide with each other, and thus the anode electrode 40 and the semiconductor material 70 contact each other. The film thickness of the semiconductor material 70 is 200 nm, for example.

Examples of a p-type semiconductor material constituting the semiconductor material 70 include Si, GaAs, SiC, Ge, ZnSe, CdS, InP, SiGe, as well as p-type oxide semiconductors, such as NiO, Cu₂O, and Ag₂O. The p-type oxide semiconductor is advantageously free from oxidation. For example, NiO is a material exhibiting only a p-type conductivity type and may be suitable for quality stabilization. Further, NiO has a band gap as large as 3.7 eV and is thus desirable as a material that takes advantage of high withstand voltage of the gallium oxide. Furthermore, in order to control acceptor concentration, about 0.2 mol % to 1.0 mol % of Li or La may be added to NiO (99.9%) as a dopant. The acceptor concentration may be equal to or larger than 5×10¹⁷ cm⁻³ and, may be equal to or larger than 5×10¹⁸ cm⁻³, for example, about 1×10¹⁹ cm⁻³ in terms of product stability. This is because when the acceptor concentration is low, the semiconductor material 70 may be depleted to fail to exhibit a desired function. Therefore, the higher the acceptor concentration, the better. However, when the acceptor concentration exceeds 1×10²² cm⁻³, film characteristics may be deteriorated, so the acceptor concentration may be equal to or less than about 5×10²¹ cm⁻³.

When the p-type oxide constituting the semiconductor material 70 is completely in an amorphous state, it may be crystallized unintentionally in a heating process during device production to lead to characteristic instability. Considering this, by crystallizing about 50 volume % of the p-type oxide at a point in time when it is formed in the outer peripheral trench 32, it is possible to reduce the influence of crystallization in the heating process during device production.

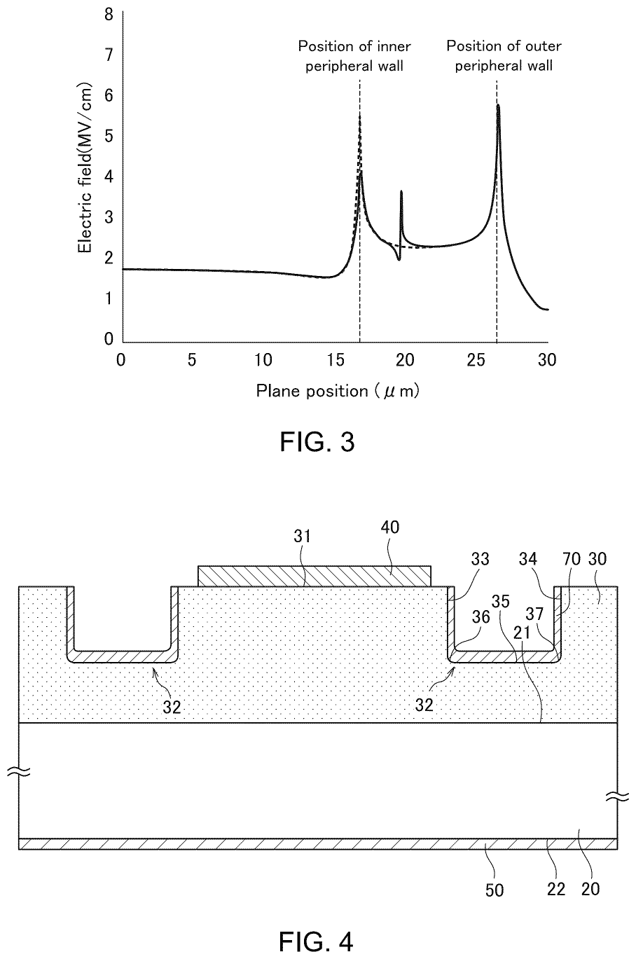

FIG. 3 is a graph illustrating the relation between field strength to be applied to the drift layer 30 upon application of a backward voltage of 1200 V and plane In this graph, the solid line denotes position. characteristics of the Schottky barrier diode 1 according to the present embodiment, and the dashed line denotes characteristics of a Schottky barrier diode according to a comparative example illustrated in FIG. 4. The Schottky barrier diode according to the comparative example of FIG. 4 differs from the Schottky barrier diode 1 according to the present embodiment in that the entire inner wall of the outer peripheral trench 32 is covered with the semiconductor material 70 having a conductivity type opposite to that of the drift layer 30.

As can be seen from the graph of FIG. 3, at the plane position of the outer peripheral wall 34, there is no difference in field strength between the Schottky barrier diode 1 according to the present embodiment and the Schottky barrier diode according to the comparative example; on the other hand, at the plane position of the inner peripheral wall 33, the field strength of the Schottky barrier diode 1 according to the present embodiment is significantly reduced as compared with the field strength of the Schottky barrier diode according to the comparative example. The position between the inner and outer peripheral walls 33 and 34 at which the field strength is locally increased corresponds to the boundary position between the anode electrode 40 and the semiconductor material 70 on the bottom surface 35.

As described above, according to the Schottky barrier diode 1 of the present embodiment, it is possible to relax field strength to be applied to the vicinity of the inner peripheral wall 33 of the drift layer 30 upon application of a backward voltage.

### Second Embodiment

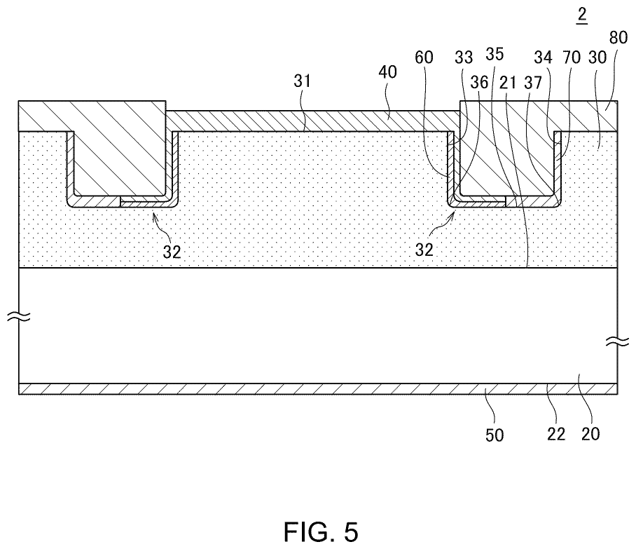

FIG. 5 is a schematic cross-sectional view illustrating the configuration of a Schottky barrier diode 2 according to a second embodiment of the present disclosure.

As illustrated in FIG. 5, the Schottky barrier diode 2 according to the second embodiment differs from the Schottky barrier diode 1 according to the first embodiment in that a field insulating film 80 is filled in the outer peripheral trench 32 so as to cover the anode electrode 40 and semiconductor material 70. Other basic configurations are the same as those of the Schottky barrier diode 1 according to the first embodiment, so the same reference numerals are given to the same elements, and overlapping description will be omitted.

Examples of the material of the field insulating film 80 may include: various resin materials including epoxy resin, acrylic resin such as polymethyl methacrylate, polyurethane, polyimide, polyvinyl alcohol, fluororesin, and polyolefin; and inorganic oxides or nitrides such as silicon oxide, aluminum oxide, and silicon nitride. When a resin material is used, the field insulating film 80 can be formed through application of a resin solution, followed by drying thereof, application or deposition of a resin monomer, followed by polymerization thereof, or cross-linking treatment after film formation. When an inorganic oxide is used, the field insulating film 80 can be formed using a vacuum process, such as a sputtering method and a vapor deposition method or a solution process such as a sol-gel method.

As exemplified in the present embodiment, the outer peripheral trench 32 may be filled with the field insulating film 80.

### Third Embodiment

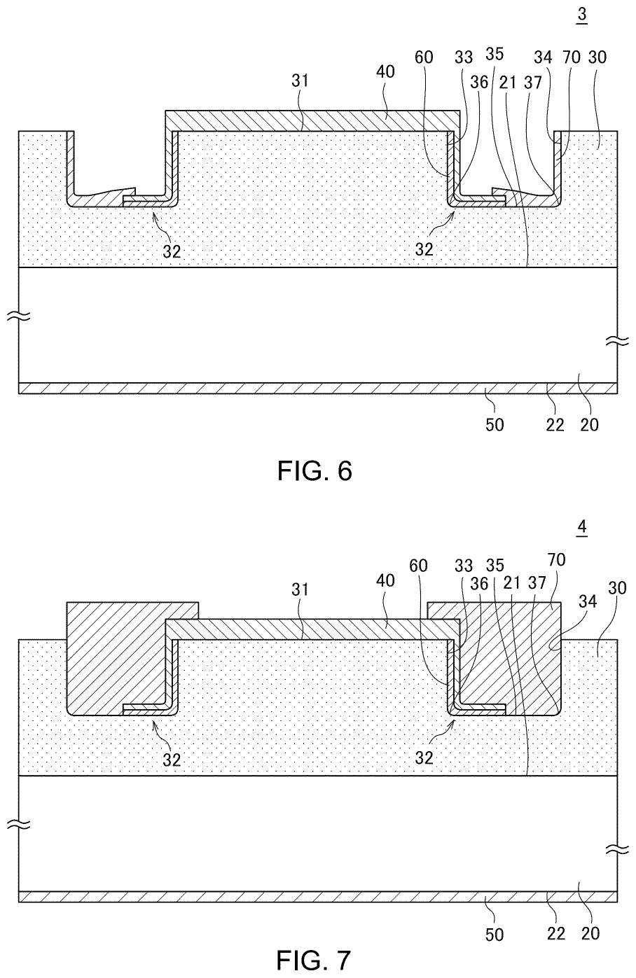

FIG. 6 is a schematic cross-sectional view illustrating the configuration of a Schottky barrier diode 3 according to a third embodiment of the present disclosure.

As illustrated in FIG. 6, the Schottky barrier diode 3 according to the third embodiment differs from the Schottky barrier diode 1 according to the first embodiment in that the semiconductor material 70 partially runs on the anode electrode 40 at the bottom surface 35 of the outer peripheral trench 32. Other basic configurations are the same as those of the Schottky barrier diode 1 according to the first embodiment, so the same reference numerals are given to the same elements, and overlapping description will be omitted.

Such a structure can be obtained by forming a laminated body of the insulating film 60 and anode electrode 40 inside the outer peripheral trench 32 and then forming the semiconductor material 70 inside the outer peripheral trench 32.

As exemplified in the present embodiment, the semiconductor material 70 may be partially formed on the anode electrode 40.

### Fourth Embodiment

FIG. 7 is a schematic cross-sectional view illustrating the configuration of a Schottky barrier diode 4 according to a fourth embodiment of the present disclosure.

As illustrated in FIG. 7, the Schottky barrier diode 4 according to the fourth embodiment differs from the Schottky barrier diode 1 according to the first embodiment in that the outer peripheral trench 32 does not have a hollow part, and the entire outer peripheral trench 32 excluding the formation part of the laminated body of insulating film 60 and anode electrode 40 is filled with the semiconductor material 70. Other basic configurations are the same as those of the Schottky barrier diode 1 according to the first embodiment, so the same reference numerals are given to the same elements, and overlapping description will be omitted.

Such a structure can be obtained by forming the laminated body of the insulating film 60 and anode electrode 40 inside the outer peripheral trench 32 and then filling the outer peripheral trench 32 with the semiconductor material 70.

As exemplified in the present embodiment, the entire outer peripheral trench 32 excluding the formation part of the laminated body of insulating film 60 and anode electrode 40 may be filled with the semiconductor material 70.

### Fifth Embodiment

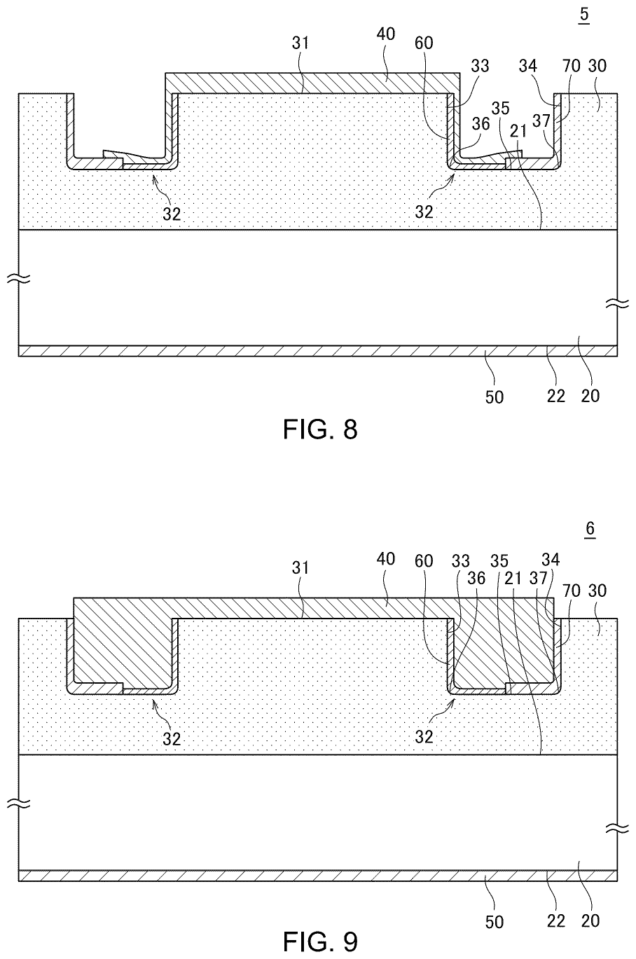

FIG. 8 is a schematic cross-sectional view illustrating the configuration of a Schottky barrier diode 5 according to a fifth embodiment of the present disclosure.

As illustrated in FIG. 8, the Schottky barrier diode 5 according to the fifth embodiment differs from the Schottky barrier diode 1 according to the first embodiment in that the anode electrode 40 partially runs on the semiconductor material 70 at the bottom surface 35 of the outer peripheral trench 32. Other basic configurations are the same as those of the Schottky barrier diode 1 according to the first embodiment, so the same reference numerals are given to the same elements, and overlapping description will be omitted.

Such a structure can be obtained by forming the semiconductor material 70 inside the outer peripheral trench 32 and then forming the anode electrode 40 inside the outer peripheral trench 32.

As exemplified in the present embodiment, the anode electrode 40 may be partially formed on the semiconductor material 70.

### Sixth Embodiment

FIG. 9 is a schematic cross-sectional view illustrating the configuration of a Schottky barrier diode 6 according to a sixth embodiment of the present disclosure.

As illustrated in FIG. 9, the Schottky barrier diode 6 according to the sixth embodiment differs from the Schottky barrier diode 1 according to the first embodiment in that the outer peripheral trench 32 does not have a hollow part, and the entire outer peripheral trench 32 excluding the formation part of the insulating film 60 and semiconductor material 70 is filled with the anode electrode 40. Other basic configurations are the same as those of the Schottky barrier diode 1 according to the first embodiment, so the same reference numerals are given to the same elements, and overlapping description will be omitted.

Such a structure can be obtained by forming the insulating film 60 and semiconductor material 70 inside the outer peripheral trench 32 and then filling the outer peripheral trench 32 with the anode electrode 40.

As exemplified in the present embodiment, the entire outer peripheral trench 32 excluding the formation part of the insulating film 60 and semiconductor material 70 may be filled with the anode electrode 40.

### Seventh Embodiment

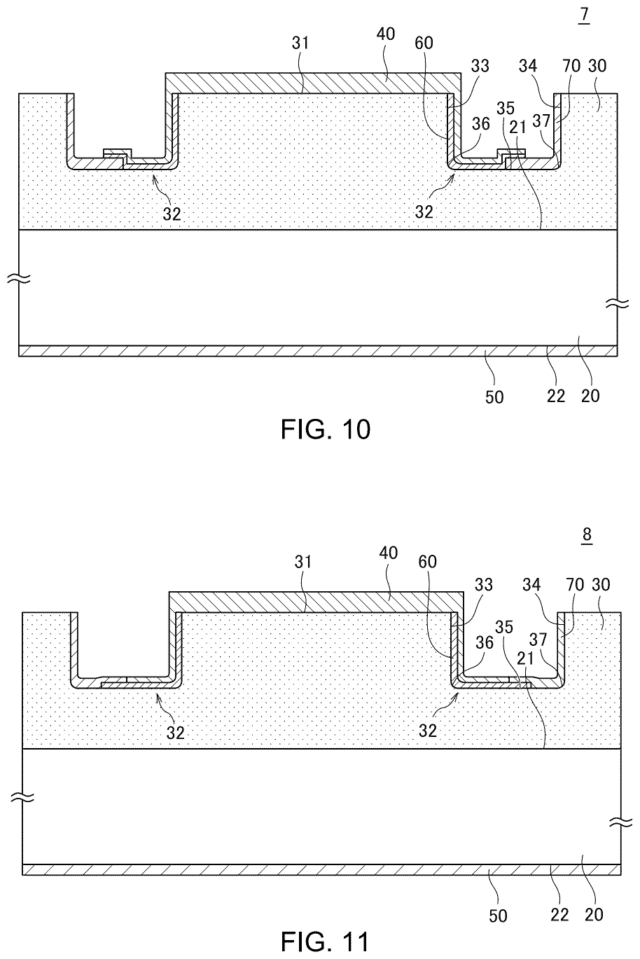

FIG. 10 is a schematic cross-sectional view illustrating the configuration of a Schottky barrier diode 7 according to a seventh embodiment of the present disclosure.

As illustrated in FIG. 10, the Schottky barrier diode 7 according to the seventh embodiment differs from the Schottky barrier diode 1 according to the first embodiment in that a laminated body of the insulating film 60 and anode electrode 40 partially runs on the semiconductor material 70 at the bottom surface 35 of the outer peripheral trench 32. Other basic configurations are the same as those of the Schottky barrier diode 1 according to the first embodiment, so the same reference numerals are given to the same elements, and overlapping description will be omitted.

Such a structure can be obtained by forming the semiconductor material 70 inside the outer peripheral trench 32 and then forming a laminated body of the insulating film 60 and anode electrode 40 inside the outer peripheral trench 32.

As exemplified in the present embodiment, the laminated body of the insulating film 60 and anode electrode 40 may be partially formed on the semiconductor material 70. In such a structure, the semiconductor material 70 does not contact the anode electrode 40 on the bottom surface 35 of the outer peripheral trench 32. The potential of the semiconductor material 70 in this case is not particularly limited, and the semiconductor material 70 may be applied with a predetermined fixed potential, or may be put in an electrically floating state. In the latter case, it is not necessary to supply a predetermined potential to the semiconductor material 70, making it possible to achieve structural simplification.

### Eighth Embodiment

FIG. 11 is a schematic cross-sectional view illustrating the configuration of a Schottky barrier diode 8 according to an eighth embodiment of the present disclosure.

As illustrated in FIG. 11, the Schottky barrier diode 8 according to the eighth embodiment differs from the Schottky barrier diode 1 according to the first embodiment in that the semiconductor material 70 partially runs on the insulating film 60 at the bottom surface 35 of the outer peripheral trench 32. Other basic configurations are the same as those of the Schottky barrier diode 1 according to the first embodiment, so the same reference numerals are given to the same elements, and overlapping description will be omitted.

Such a structure can be obtained by forming the insulating film 60 inside the outer peripheral trench 32 and then forming the semiconductor material 70 and anode electrode 40 inside the outer peripheral trench 32.

As exemplified in the present embodiment, the lower surface of the semiconductor material 70 may contact the upper surface of the insulating film 60.

### Ninth Embodiment

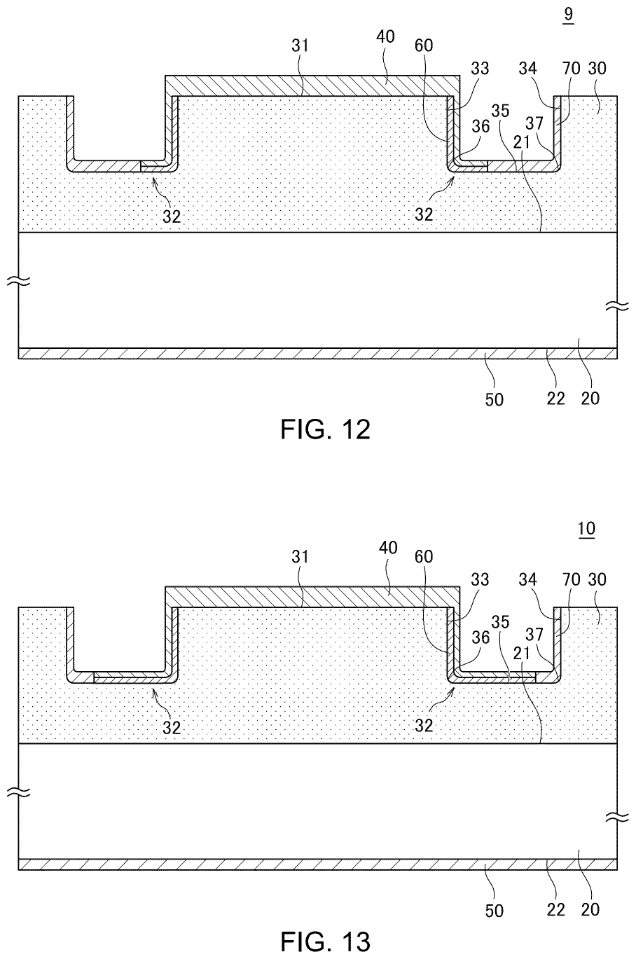

FIG. 12 is a schematic cross-sectional view illustrating the configuration of a Schottky barrier diode 9 according to a ninth embodiment of the present disclosure.

As illustrated in FIG. 12, the Schottky barrier diode 9 according to the ninth embodiment differs from the Schottky barrier diode 1 according to the first embodiment in that the boundary position between the laminated body of the insulating film 60 and anode electrode 40 and the semiconductor material 70 is offset toward the inner peripheral corner 36 of the outer peripheral trench 32 from the center of the bottom surface 35. Other basic configurations are the same as those of the Schottky barrier diode 1 according to the first embodiment, so the same reference numerals are given to the same elements, and overlapping description will be omitted.

Even in this case, the same effects as those obtained by the Schottky barrier diode 1 according to the first embodiment can be obtained provided that the inner peripheral corner 36 of the outer peripheral trench 32 is covered with the laminated body of the insulating film 60 and anode electrode 40.

### Tenth Embodiment

FIG. 13 is a schematic cross-sectional view illustrating the configuration of a Schottky barrier diode 10 according to a tenth embodiment of the present disclosure.

As illustrated in FIG. 13, the Schottky barrier diode 10 according to the tenth embodiment differs from the Schottky barrier diode 1 according to the first embodiment in that the boundary position between the laminated body of the insulating film 60 and anode electrode 40 and the semiconductor material 70 is offset toward the outer peripheral corner 37 of the outer peripheral trench 32 from the center of the bottom surface 35. Other basic configurations are the same as those of the Schottky barrier diode 1 according to the first embodiment, so the same reference numerals are given to the same elements, and overlapping description will be omitted.

Even in this case, the same effects as those obtained by the Schottky barrier diode 1 according to the first embodiment can be obtained provided that the outer peripheral corner 37 of the outer peripheral trench 32 is covered with the semiconductor material 70.

### Eleventh Embodiment

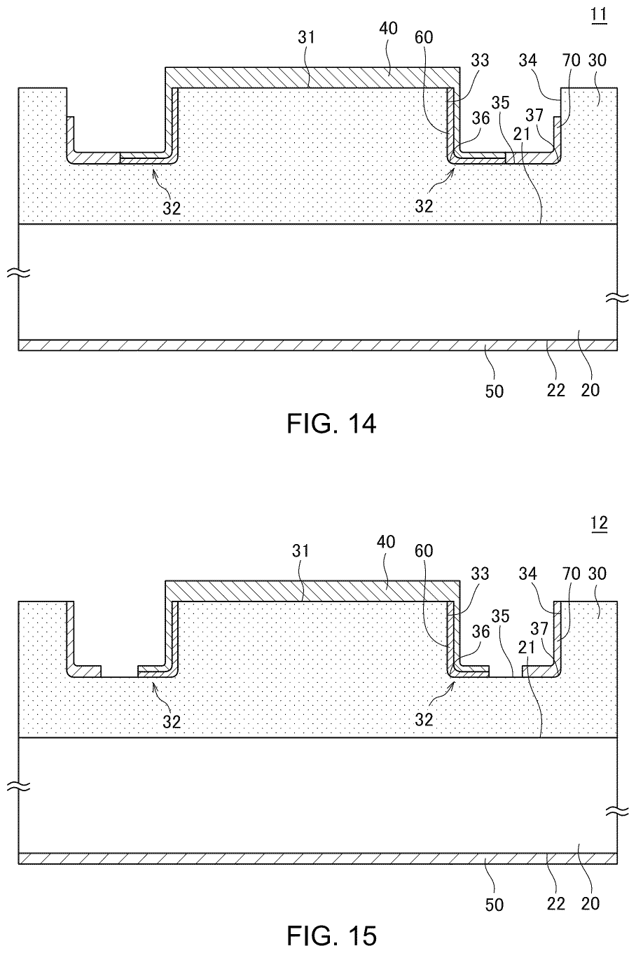

FIG. 14 is a schematic cross-sectional view illustrating the configuration of a Schottky barrier diode 11 according to an eleventh embodiment of the present disclosure.

As illustrated in FIG. 14, the Schottky barrier diode 11 according to the eleventh embodiment differs from the Schottky barrier diode 1 according to the first embodiment in that the upper portion of the outer peripheral wall 34 of the outer peripheral trench 32 is exposed without being covered with the semiconductor material 70. Other basic configurations are the same as those of the Schottky barrier diode 1 according to the first embodiment, so the same reference numerals are given to the same elements, and overlapping description will be omitted.

As exemplified in the present embodiment, the outer peripheral wall 34 of the outer peripheral trench 32 need not be covered completely with the semiconductor material 70 so long as at least the outer peripheral corner 37 is covered with the semiconductor material 70.

### Twelfth Embodiment

FIG. 15 is a schematic cross-sectional view illustrating the configuration of a Schottky barrier diode 12 according to a twelfth embodiment of the present disclosure.

As illustrated in FIG. 15, the Schottky barrier diode 12 according to the twelfth embodiment differs from the Schottky barrier diode 1 according to the first embodiment in that the bottom surface 35 of the outer peripheral trench 32 is partially exposed without being covered with the laminated body of the insulating film 60 and anode electrode 40 or the semiconductor material 70. Other basic configurations are the same as those of the Schottky barrier diode 1 according to the first embodiment, so the same reference numerals are given to the same elements, and overlapping description will be omitted.

As exemplified in the present embodiment, the bottom surface 35 of the outer peripheral trench 32 need not be covered completely with the laminated body of the insulating film 60 and anode electrode 40 or the semiconductor material 70 but may be partially exposed.

### Thirteenth Embodiment

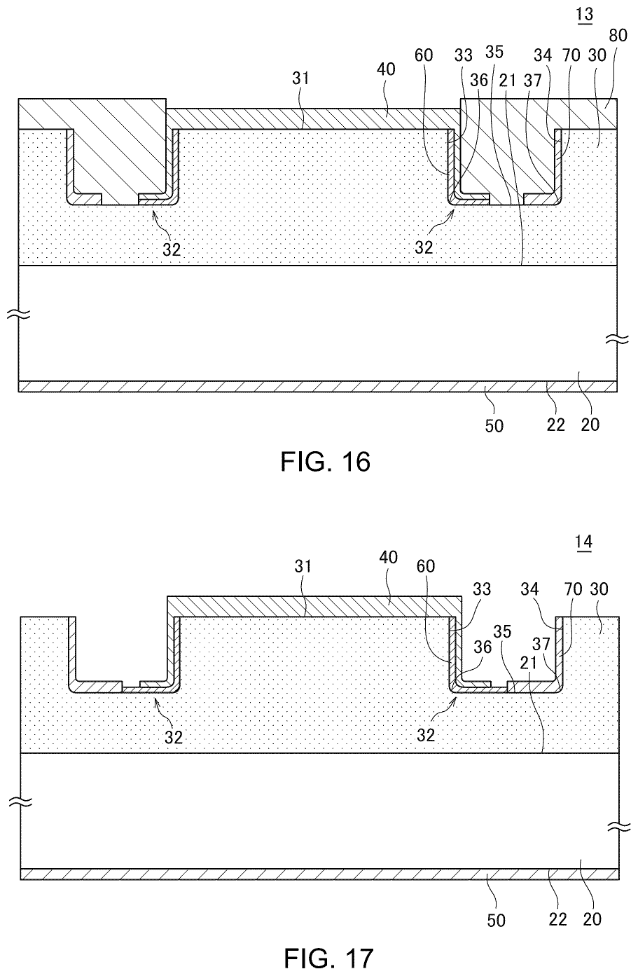

FIG. 16 is a schematic cross-sectional view illustrating the configuration of a Schottky barrier diode 13 according to a thirteenth embodiment of the present disclosure.

As illustrated in FIG. 16, the Schottky barrier diode 13 according to the thirteenth embodiment differs from the Schottky barrier diode 12 according to the twelfth embodiment in that the field insulating film 80 is filled in the outer peripheral trench 32 so as to cover the anode electrode 40 and semiconductor material 70. Other basic configurations are the same as those of the Schottky barrier diode 12 according to the twelfth embodiment, so the same reference numerals are given to the same elements, and overlapping description will be omitted.

In the present embodiment, the bottom surface 35 of the outer peripheral trench 32 is partially exposed, and thus the field insulating film 80 partially contacts the bottom surface 35 of the outer peripheral trench 32. Thus, the field insulating film 80 may partially contact the bottom surface 35 of the outer peripheral trench 32.

### Fourteenth Embodiment

FIG. 17 is a schematic cross-sectional view illustrating the configuration of a Schottky barrier diode 14 according to a fourteenth embodiment of the present disclosure.

As illustrated in FIG. 17, the Schottky barrier diode 14 according to the fourteenth embodiment differs from the Schottky barrier diode 1 according to the first embodiment in that the end face position of the anode electrode 40 is offset toward the inner peripheral corner 36 of the outer peripheral trench 32 from the center of the bottom surface 35 and, accordingly, the insulating film 60 is partially exposed without being covered with the anode electrode 40. Other basic configurations are the same as those of the Schottky barrier diode 1 according to the first embodiment, so the same reference numerals are given to the same elements, and overlapping description will be omitted.

Even in this case, the same effects as those obtained by the Schottky barrier diode 1 according to the first embodiment can be obtained provided that the inner peripheral wall 33 and inner peripheral corner 36 of the outer peripheral trench 32 is covered with the laminated body of the insulating film 60 and anode electrode 40.

### Fifteenth Embodiment

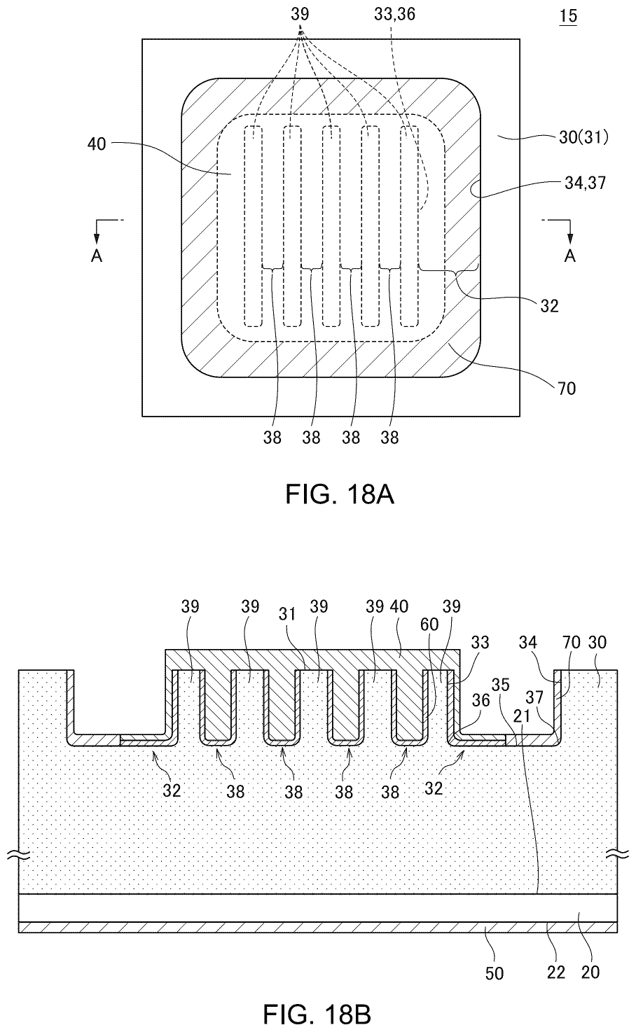

FIG. 18A is a schematic plan view illustrating the configuration of a Schottky barrier diode 15 according to a fifteenth embodiment of the present disclosure. FIG. 18B is a schematic cross-sectional view taken along the line A-A in FIG. 18A.

As illustrated in FIG. 18, the Schottky barrier diode 15 according to the fifteenth embodiment differs from the Schottky barrier diode 1 according to the first embodiment in that a plurality of center trenches 38 are formed in the drift layer 30 so as to be surrounded by the outer peripheral trench 32 and are filled with the anode electrode 40 through the insulating film 60. Other basic configurations are the same as those of the Schottky barrier diode 1 according to the first embodiment, so the same reference numerals are given to the same elements, and overlapping description will be omitted.

All the plurality of center trenches 38 are formed so as to overlap the anode electrode 40 in a plan view. An area of the drift layer 30 that is sandwiched between the trenches (outer peripheral trench 32 and center trench 38 or adjacent center trenches 38) constitutes a mesa region 39. The outer peripheral trench 32 surrounds in a ring-shaped manner the center trenches 38 and mesa regions 39. The outer peripheral trench 32 and center trenches 38 need not be completely separated from each other but may be connected to each other as illustrated in FIG. 18A. The depth of the center trenches 38 and that of the outer peripheral trench 32 may be the same or different. The mesa region 39 is a part of the drift layer 30 that is defined by the center trenches 38 and outer peripheral trench 32 and becomes a depletion layer when a backward voltage is applied between the anode electrode 40 and the cathode electrode 50, so that a channel region of the drift layer 30 is pinched off. Thus, a leak current upon application of a backward voltage is significantly reduced.

As exemplified in the present embodiment, the center trenches 38 surrounded by the outer peripheral trench 32 may be formed in the drift layer 30.

While the some embodiments of the present disclosure has been described, the present disclosure is not limited to the above embodiment, and various modifications may be made within the scope of the present disclosure, and all such modifications are included in the present disclosure.

The technology according to the present disclosure includes the following configuration examples, but not limited thereto.

A Schottky barrier diode according to the present disclosure includes: a semiconductor substrate; a drift layer provided on the semiconductor substrate; an anode electrode brought into Schottky contact with the drift layer; and a cathode electrode brought into ohmic contact with the semiconductor substrate. The drift layer has an outer peripheral trench surrounding the anode electrode in a plan view. The outer peripheral trench includes an inner peripheral wall, an outer peripheral wall, a bottom surface, an inner peripheral corner connecting the inner peripheral wall and the bottom surface, and an outer peripheral corner connecting the outer peripheral wall and the bottom surface. The inner peripheral wall of the outer peripheral trench and the inner peripheral corner of the outer peripheral trench are covered with the anode electrode through an insulating film, and the outer peripheral corner of the outer peripheral trench is covered with a semiconductor material having a conductivity type opposite to a conductivity type of the drift layer.

According to the present disclosure, it is possible to relax a magnetic field generated at a part of the drift layer that is in the vicinity of the inner peripheral corner upon application of a backward voltage.

In the present disclosure, the semiconductor material may be in an electrically floating state. This eliminates the need of supplying a predetermined potential to the semiconductor material.

In the present disclosure, the drift layer may further have a plurality of center trenches surrounded by the outer peripheral trench and filled with the anode electrode. Thus, a mesa region positioned between the center trenches becomes a depletion layer upon application of a backward voltage, so that a channel region of a drift layer is pinched off. This can significantly reduce a leak current upon application of a backward voltage.

As described above, according to the present disclosure, it is possible to further relax, in a Schottky barrier diode, an electric field generated in the drift layer upon application of a backward voltage.

1. A Schottky barrier diode comprising:
a semiconductor substrate;
a drift layer provided on the semiconductor substrate;
an anode electrode brought into Schottky contact with the drift layer; and
a cathode electrode brought into ohmic contact with the semiconductor substrate,
wherein the drift layer has an outer peripheral trench surrounding the anode electrode in a plan view,
wherein the outer peripheral trench includes an inner peripheral wall, an outer peripheral wall, a bottom surface, an inner peripheral corner connecting the inner peripheral wall and the bottom surface, and an outer peripheral corner connecting the outer peripheral wall and the bottom surface,
wherein the inner peripheral wall of the outer peripheral trench and the inner peripheral corner of the outer peripheral trench are covered with the anode electrode through an insulating film, and
wherein the outer peripheral corner of the outer peripheral trench is covered with a semiconductor material having a conductivity type opposite to a conductivity type of the drift layer.

2. The Schottky barrier diode as claimed in claim 1, wherein the semiconductor material is in an electrically floating state.

3. The Schottky barrier diode as claimed in claim 1, wherein the drift layer further has a plurality of center trenches surrounded by the outer peripheral trench and filled with the anode electrode.

4. The Schottky barrier diode as claimed in claim 2, wherein the drift layer further has a plurality of center trenches surrounded by the outer peripheral trench and filled with the anode electrode.
